(19) United States
(12) Patent Application Publication
(10) Pub. No.: US 2025/0118679 A1
(43) Pub. Date: Apr. 10, 2025

(54) FIELD EFFECT TRANSISTOR WITH ALIGNMENT MARK AND RELATED METHODS

(71) Applicant: Taiwan Semiconductor Manufacturing Co., Ltd., Hsinchu (TW)

(72) Inventors: Chih-Hsiung PENG, Hsinchu (TW); Shih-Chi FU, Hsinchu (TW); Kuei-Shun CHEN, Hsinchu (TW); Yu-Lun LIU, Hsinchu (TW)

(21) Appl. No.: 18/483,657

(22) Filed: Oct. 10, 2023

(51) Int. Cl. H01L 23/544; H01L 21/308; H01L 21/3105; H01L 21/8234

(52) U.S. Cl. CPC H01L 23/544; H01L 21/3081; H01L 21/31053; H10D 84/0156; H10D 84/038; H01L 2223/54426

(57) ABSTRACT

A method includes: forming a first mask over a substrate; forming first openings and a second opening in the first mask; forming first wells in first regions of the substrate exposed by the first openings and an alignment implant in a second region of the substrate exposed by the second opening; forming an alignment mark by recessing the alignment implant; and patterning a multi-layer semiconductor lattice under alignment of the alignment mark.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-9 are diagrammatic cross-sectional side views of a portion of an IC device at various stages of fabrication according to embodiments of the present disclosure.

FIG. 10 is a flowchart of a method of forming an IC device in accordance with various embodiments.

FIG. 11 is a diagrammatic cross-sectional side view of a portion of an IC in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The terms “first,” “second,” “third” and so on may be used herein to describe a sequence of events or sequential order of elements but may be exchanged or varied in some contexts. For example, a second layer may be formed on (e.g., sequentially after) a first layer, but in some contexts the first layer may be referred to as a “second layer,” “third layer,” “fourth layer” or the like, and the second layer may be referred to as a “first layer,” “third layer,” “fourth layer,” or the like.

The term “surrounds” may be used herein to describe a structure that fully or partially encloses another element or structure, for example, in three dimensions. For example, a first structure may “surround” a second structure on four lateral sides (e.g., left, right, front and back) without surrounding the second structure on two vertical sides (e.g., top and bottom). In other example, the first structure may wrap partially around the second structure, for example, by wrapping around three sides (e.g., top, front and back) while leaving other sides (e.g., left, right and bottom) exposed.

The present disclosure is generally related to semiconductor devices, and more particularly to field-effect transistors (FETs), such as planar FETs, three-dimensional fin FETs (FinFETs), or nanostructure FETs, such as nanosheet FETs (NSFETs), nanowire FETs (NWFETs), gate-all-around FETs (GAAFETs) and the like.

Semiconductor devices may be formed by performing a sequence of many operations. For example, a deposition or epitaxial growth operation may form a material layer on a surface of a wafer. A photolithography operation may form a mask that protects some regions and exposes other regions of the material layer according to a pattern. An etch operation may form openings by removing some or all of material of the material layer in the exposed regions. Then, another deposition or epitaxial growth operation may be performed to form another material layer in the openings.

During a photolithography exposure process, material layers of the semiconductor devices may be exposed to different patterns on a photomask in different operations. A substrate or wafer may include many regions, each of which is exposed using the same or different photomasks. To stack patterns correctly at each exposure, alignment marks and overlay marks may be used with other methods. An overlay margin may be built into the design to allow for small errors in alignment. For example, the overlay margin ensures that even if an error occurs during alignment, resulting features do not overlap each other, which can cause a defect in the final device. The effect of using overlay margins is cumulative because alignment errors may be additive in different regions of the semiconductor substrate. As feature sizes decrease, the effect of cumulative overlay margins can reduce gains from total device area from the smaller features.

A zero mark, also known as a “reference mark” or “baseline mark,” is a type of alignment mark used as a reference point during the alignment process. The zero mark serves as a fixed point of reference that has position precisely known relative to a wafer's coordinates. The “zero mark” can refer to a mark that is formed in the base silicon wafer or “zeroth layer” thereof. The wafer may be coated with various materials to create the different layers of the IC device as described above. In the photolithography operation, a photosensitive layer such as photoresist is applied to the wafer's surface. The photoresist is then exposed to light through a photomask, which contains the pattern of the layer to be created. To stack multiple layers precisely, one or more alignment marks are present on the wafer, which may include the zero mark. Sensors or cameras in the lithography equipment may detect the alignment marks. The lithography equipment uses the zero mark as a reference point to align the pattern on the photomask precisely with respect to already existing features on the wafer. The equipment adjusts the position and orientation of the mask or the wafer to ensure proper alignment. After alignment, the photolithography process continues, and the pattern on the photomask is transferred onto the photoresist on the wafer. Once the pattern is formed on the wafer through photolithography, additional steps like etching or deposition are carried out to etch away or add selected materials, respectively, creating features of the IC device. The process may be repeated for each layer of the IC device, and precise alignment improves accuracy in stacking different layers upon each other. By using zero marks as reference points, beneficial precision in the IC manufacturing process may be achieved, leading to high-performance and reliable electronic devices.

In many IC devices, an operation that follows soon after formation of the zero mark in the base silicon is formation of implant wells or well regions in which oxide diffusion or oxide definition (OD) areas or active areas of devices may be subsequently formed. Prior to formation of wells, the wafer may be cleaned and prepared for further processing. Then, a layer of photoresist is applied to the wafer's surface, and a photomask with the desired pattern is used to expose the photoresist under alignment of the zero mark that was formed prior to application of the photoresist. The pattern selects locations where wells will be formed. The wafer may then be exposed to high-energy ions of a selected dopant species via ion implantation. The ions penetrate the wafer's surface and come to rest at a selected depth, creating the well regions. The dopant species used can depend on type of wells to be formed (e.g., n-type or p-type). After ion implantation, the wafer may undergo an annealing process to activate the dopant atoms and repair any damage caused by the implantation. In many IC devices, the well regions are isolated from each other by shallow trench isolation (STI) or other isolation techniques. Use of the zero mark to align the photolithography exposure of the photoresist can be considered a type of “indirect alignment,” which introduces error in positioning of the well regions.

In embodiments of the disclosure, a “direct” or “self-aligned” method of aligning patterning of well regions for implantation improves accuracy of positioning the well regions and of positioning subsequently formed OD regions. A self-aligned alignment mark or “p-well” (PWL) alignment mark is formed during formation of first well regions, such as p-well regions. The self-aligned alignment mark may then be used during formation of second well regions, such as n-well regions. Then, the self-aligned alignment mark may be used during OD patterning. “OD patterning” can refer to patterning that forms fins in which nanosheet channels may be positioned. Because the first and second well regions and the subsequent fins are directly aligned via the self-aligned alignment mark instead of indirectly aligned by the zero mark, the fins can be accurately positioned in the first and second well regions. This can be beneficial to improving device reliability and performance.

Nanostructure transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure structure.

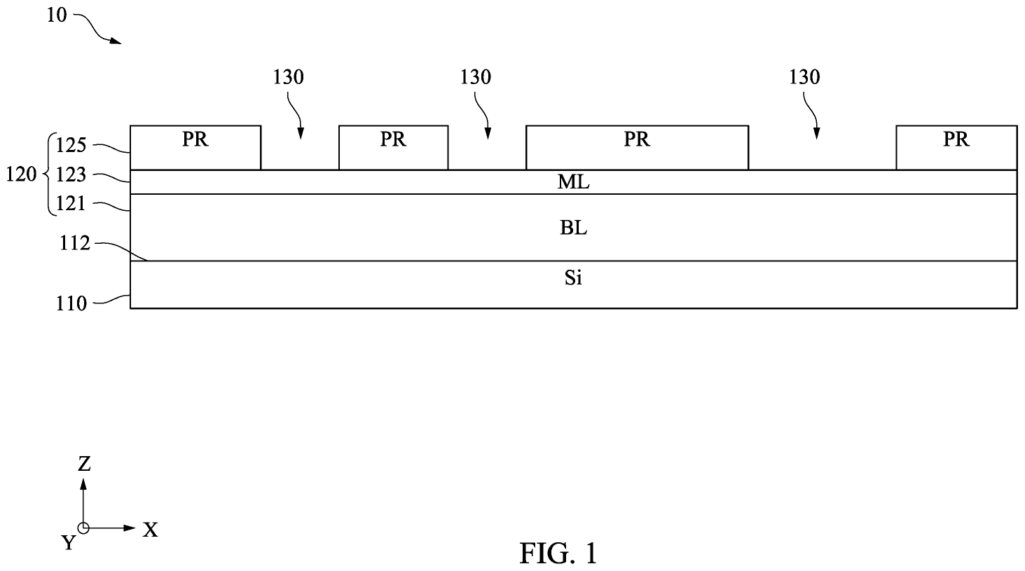

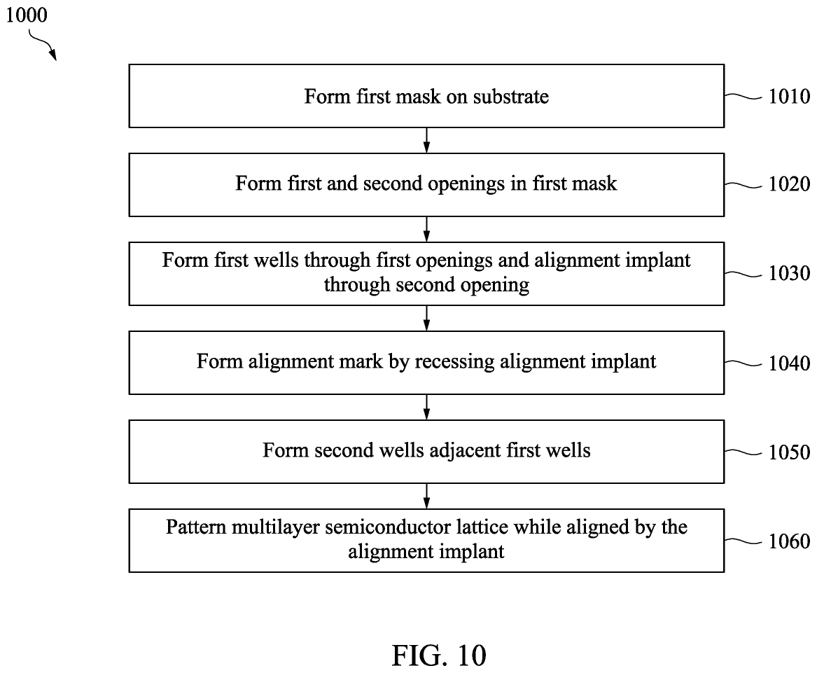

FIGS. 1-8 are diagrammatic cross-sectional side views of a portion of an IC device at various stages of fabrication according to embodiments of the present disclosure. FIG. 10 illustrates a flowchart of method 1000 for forming an IC device or a portion thereof from a workpiece, according to one or more aspects of the present disclosure. Method 1000 is merely an example and is not intended to limit the present disclosure to what is explicitly illustrated in method 1000. Additional acts can be provided before, during and after the method 1000 and some acts described can be replaced, eliminated, or moved around for additional embodiments of the method. Not all acts are described herein in detail for reasons of simplicity. Method 1000 is described below in conjunction with fragmentary perspective and/or cross-sectional views of a workpiece, shown in FIGS. 1-8, at different stages of fabrication according to embodiments of method 1000. For avoidance of doubt, throughout the figures, the X direction is perpendicular to the Y direction and the Z direction is perpendicular to both the X direction and the Y direction. It is noted that, because the workpiece may be fabricated into a semiconductor device, the workpiece may be referred to as the semiconductor device as appropriate to the context.

In FIG. 1, a substrate 110 is provided. The substrate 110 may be a semiconductor substrate, such as a bulk semiconductor, or the like, which may be doped (e.g., with a p-type or an n-type dopant) or undoped. The semiconductor material of the substrate 110 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

On the substrate 110, a first mask 120 may be formed, corresponding to act 1010 of FIG. 10. The first mask 120 may include a bottom mask layer 121 on and in direct contact with the substrate 110, one or more middle mask layers 123 on the bottom mask layer 121, and a photosensitive layer 125 on the middle mask layer 123.

The bottom mask layer 121 is formed on an upper surface 112 of the substrate 110. The bottom mask layer 121 may be a spin on carbon (SOC) layer 121. Spin on carbon materials are used as anti-reflective layers to planarize uneven topography or as a bottom layer of a tri-layer photoresist in semiconductor manufacturing methods. The SOC materials are coated over a substrate and then may undergo a crosslinking operation between a polymer and a crosslinker in some embodiments. The crosslinking operation may be a thermal crosslinking operation. The SOC layer is heated to initiate the thermal crosslinking operation. In some embodiments, the SOC layer 121 is deposited as a liquid mixture and the substrate 110 is rotated while the SOC layer is deposited over the substrate 110. In some embodiments, the SOC layer 121 includes a SOC composition including a carbon backbone polymer, a first crosslinker and a second crosslinker. In some embodiments, the spin on carbon composition includes a solvent. In some embodiments, the solvent is chosen such that the polymers and crosslinkers can be evenly dissolved into the solvent and dispensed upon the substrate.

In some embodiments, a non-linked SOC layer is formed to a thickness ranging from about 200 nm to about 2,000 nm. In some embodiments, the thickness of non-linked SOC layer ranges from about 400 nm to about 1,500 nm, and in other embodiments, the thickness of the non-linked SOC layer ranges from about 500 nm to about 1,200 nm depending on the underlying structures (topology), design requirements, and/or process requirements.

The SOC layer 121 may be subjected to a first heating at a temperature ranging from about 100° C. to about 170° C. to form a partially crosslinked SOC layer. In some embodiments, the first heating is at a temperature ranging from about 100° C. to about 150° C. After the first heating, the partially crosslinked SOC layer may be allowed to cool. Then, the partially crosslinked SOC layer is subsequently subjected to a second heating at a second temperature higher than the first temperature to form a further or fully crosslinked SOC layer, which may be the SOC layer 121. In some embodiments, the second temperature ranges from about 170° C. to about 300° C.

Following formation of the SOC layer 121, the one or more middle mask layers 123 are formed. The middle layer 123 of the tri-layer resist structure 120 may have a composition that provides anti-reflective properties for the photolithography operation and/or hard mask properties. In some embodiments, the middle layer 123 includes a silicon containing layer (e.g., a silicon hard mask material). In some embodiments, the middle layer 123 is a silicon-containing anti-reflective coating (SiARC) layer. The middle layer 123 may include a silicon-containing inorganic polymer. In other embodiments, the middle layer 123 includes a siloxane polymer. In other embodiments, the middle layer 123 includes silicon oxide (e.g., spin-on glass (SOG)), silicon nitride, silicon oxynitride, polycrystalline silicon, a metal-containing organic polymer material that contains a metal such as titanium, titanium nitride, aluminum, and/or tantalum, and/or other suitable materials. The middle layer 123 may be bonded to adjacent layers, such as by covalent bonding, hydrogen bonding, or hydrophilic-to-hydrophilic forces.

The photoresist layer 125 is a photosensitive layer that is patterned by exposure to actinic radiation and development. Typically, the chemical properties of the photoresist regions struck by incident radiation change in a manner that depends on the type of photoresist used. Whether a resist is positive tone or negative tone may depend on the type of developer used to develop the resist. For example, some positive tone photoresists provide a positive pattern, (i.e.—the exposed regions are removed by the developer), when the developer is an aqueous-based developer, such as a tetramethylammonium hydroxide (TMAH) solution. On the other hand, the same photoresist provides a negative pattern (i.e.—the unexposed regions are removed by the developer) when the developer is an organic solvent. Further, in some negative tone photoresists developed with the TMAH solution, the unexposed regions of the photoresist are removed by the TMAH, and the exposed regions of the photoresist, that undergo cross-linking upon exposure to actinic radiation, remain on the substrate after development.

The structure of FIG. 1 is subsequently processed to form first openings 130 and a second opening 132. Forming the openings may include developing the photoresist layer 125 according to a pattern of a photomask. For example, a portion of the photoresist layer 125 is selectively exposed to actinic radiation. In some embodiments, a photomask is used to form exposed portions and unexposed portions of the photoresist layer 125. In some embodiments, the exposure to radiation is carried out by placing the photoresist-coated substrate in a photolithography tool. The photolithography tool includes a photomask, optics, an exposure radiation source to provide the radiation for exposure and a movable stage for supporting and moving the substrate under the exposure radiation. In some embodiments, the selective exposure of the photoresist layer 125 to form exposed regions and unexposed regions is performed using deep ultraviolet (DUV) lithography. For example, the selective exposure may be by an ArF excimer laser having wavelength of about 193 nm. Development is subsequently performed using a solvent to form openings 130, 132 in the photoresist layer.

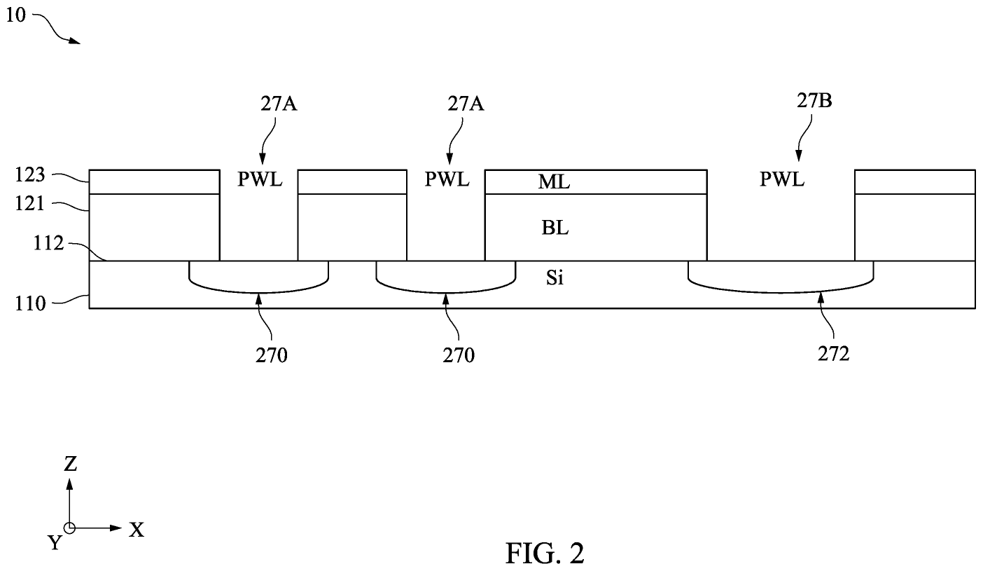

In FIG. 2, following formation of the first and second openings 130, 132 in the photoresist 125, first and second openings 27A, 27B are formed by etching the middle layer 123 and bottom layer 121 etched using the patterned photoresist 125 as an etch mask to extend the openings 130, 132, corresponding to act 1020 of FIG. 10. The middle layer 123 and bottom layer 121 may be etched by wet or dry etching. In some embodiments, the openings 27A, 27B expose the substrate 110. Then, the remaining portions of the photoresist 125 may be removed by one or more stripping or etching operations, as shown in FIG. 2.

Further in FIG. 2, first wells 270 and a second well 272 are formed through the first openings 27A and the second opening 27B, respectively, corresponding to act 1030 of FIG. 10. The first wells 270 may be wells that are for forming active areas (e.g., fins, channels and source/drains) and the second well 272 may be a well that is for use as an alignment mark in subsequent processes, such as forming fins from a multilayer semiconductor lattice. The first wells 270 may be referred to as active wells 270 and the second well 272 may be referred to as an alignment well 272.

The first wells 270 and the second well 272 may be formed by an implantation process, such as an ion implantation process, or “IMP.” Ion implantation forms regions doped with selected ions (in a device or structure) to alter chemical, physical and/or electrical properties of the regions. In an IMP process, accelerated ions impinge a region of a substrate so these ions can be implanted into the substrate as dopants at selected locations to selected depths. These dopants can enable the device or structure to have selected properties, which are beneficial for various applications.

An ion beam may be produced by an ion source or an accelerator (not shown) and contains accelerated ions (e.g., primary ions) of high energy for bombarding a target on a target surface. For example, the target may be exposed regions of the substrate 110 and the target surface may be the upper surface 112 thereof. The target can represent any suitable solid material (e.g., undoped silicon of the wafer) and include a plurality of atoms. Ions of the ion beam can travel in the atoms of the target after being implanted into the target. For example, some ions may collide with atoms, other ions may be ejected after colliding with atoms, yet other ions may be implanted in atoms, and yet further ions may be channeling ions that penetrate through atoms of the target. The ion beam can impinge the target surface from various directions, and ions (e.g., primary ions) can be implanted or ejected, depending on a tilt angle of the ion beam. The ion beam may be incident on the target surface (e.g., the surface 112) at tilt angle of about 0 degrees to about 15 degrees. The ejected ions can be referred to as “secondary ions.”

In some embodiments, the first wells 270 and the second well 272 are p-type wells or “p-wells” that are doped with dopant ions suitable for forming p-type doped semiconductors. For example, the dopant ions may be ions of boron, aluminum, gallium or the like. Dimensions (e.g., width, length and depth) of the first wells 270 and the second well 272 may be about the same or different. For example, width in the X-axis direction of the second well 272 may exceed that of each of the first wells 270. The first wells 270 and the second well 272 may have the same depth due to being formed in the same implantation operation. Namely, energy of the ion beam that implants the dopant ions into the first wells 270 and the second well 272 is the same, so the depth of each may be about the same. Dopant type and concentration of the first wells 270 and the second well 272 are also substantially the same due to being formed in the same implantation operation. The first wells 270 and the second well 272 may have similar profile due to similar tilt angle characteristics. In some embodiments, as shown in FIG. 2, the first wells 270 and the second well 272 may each extend beneath the bottom mask layer 121 along the X-axis direction.

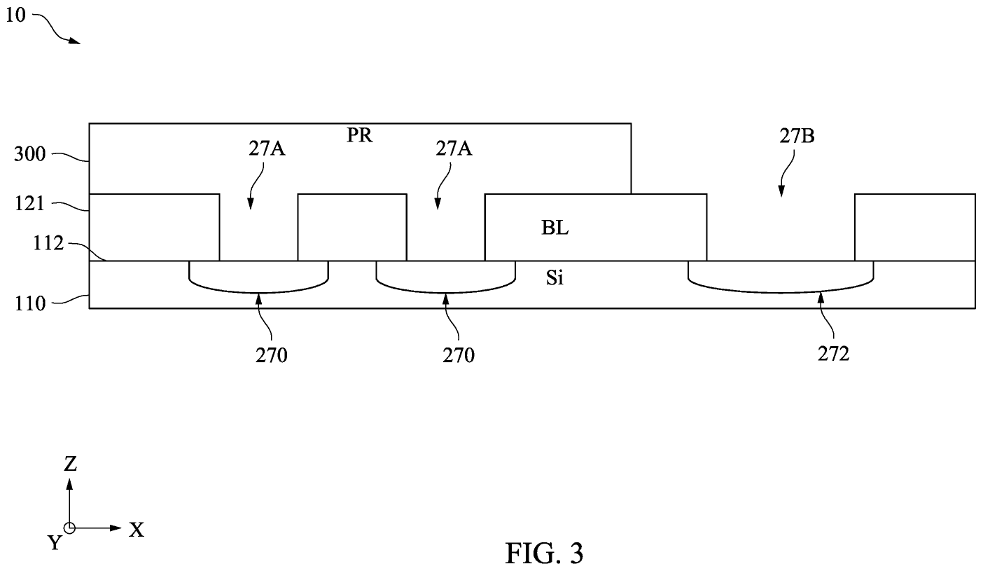

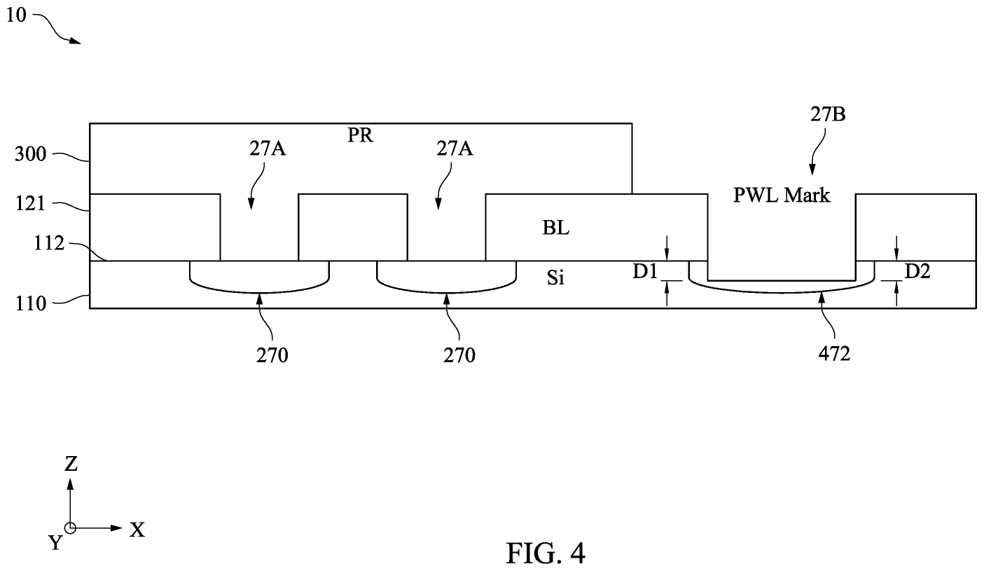

In FIGS. 3 and 4, following formation of the first and second wells 270, 272, a well alignment mark (or “implant alignment mark”) 472 is formed by removing a portion of (or “recessing”) the alignment well 272, corresponding to act 1040 of FIG. 10. A second mask 300 may be formed that covers the active wells 270 and exposes the alignment well 272, as shown. The second mask 300 may be a photosensitive layer or multilayer and may be formed in a manner similar to that described with reference to FIG. 1. The second mask 300 may be a “global” mask that substantially covers the entire wafer other than the alignment well or wells 272. For example, the second mask 300 may fill the openings 27A while leaving the opening 27B exposed. It should be understood that the well alignment mark 472 is formed using the same bottom mask layer 121 that is used for forming the first wells 270, such that the well alignment mark 472 is self-aligned with the first wells 270. Namely, the bottom mask layer 121 is not removed by ashing prior to forming the well alignment mark 472, but instead is used as a hard mask for forming the well alignment mark 472.

In some embodiments, patterning of the second mask 300 may be by exposure using a lower-frequency wavelength than is used to pattern the first mask 120. For example, the first mask 120 may be patterned using an ArF excimer laser having a first deep ultraviolet (DUV) wavelength of about 193 nm and the second mask 300 may instead be patterned using a KrF excimer laser having a second DUV wavelength of about 248 nm. In another example, the first mask 120 may be patterned by EUV light (e.g., about 13.5 nm) and the second mask 300 may be patterned by deep ultraviolet (DUV) light (e.g., about 248 nm). This is different from the zero mark, which is patterned using the ArF excimer laser having the first DUV wavelength of about 193 nm. Namely, an operation of recessing the alignment well 272 to form the well alignment mark 472 may have the benefit of being simpler than that of recessing the substrate to form the zero mark.

FIG. 4 depicts recessing of the alignment well 272 through the opening 27B to form the well alignment mark 472. In some embodiments, the opening 27B is extended partially into the alignment well 272 by an appropriate etching operation. For example, the etching of a p-well may use a selective process with KOH as an etchant, which preferentially etches the p-type silicon while leaving other regions, such as n-type silicon or undoped silicon of the substrate 110 and material of the bottom mask layer 121, relatively unaffected. The process may be performed at elevated temperatures to increase the etch rate and maintain control over the etching parameters. The etching process may be anisotropic. Selected etching conditions, such as temperature, concentration, and etching time, may be selected to achieve a selected etch depth and sidewall profile. Choice of etchant may vary. Other etchants, such as tetramethylammonium hydroxide (TMAH), can also be used for etching into p-type wells such as the alignment well 272.

The well alignment mark 472 may extend to a first depth D1 into the substrate 110. The first depth D1 may be measured from the upper surface 112 of the substrate 110 to a bottommost level of the well alignment mark 472. The recess in the well alignment mark 472 may extend to a second depth D2 that is shallower than the first depth D1. Namely, the recess does not extend fully through the well alignment mark 472, but instead stops short of the bottommost level of the well alignment mark 472. In some embodiments, a ratio of the second depth D2 over the first depth D1 is in a range of about 0.1 to about 0.9. In some embodiments, a ratio of the second depth D2 over the first depth D1 is in a range of about 0.5 to about 0.8.

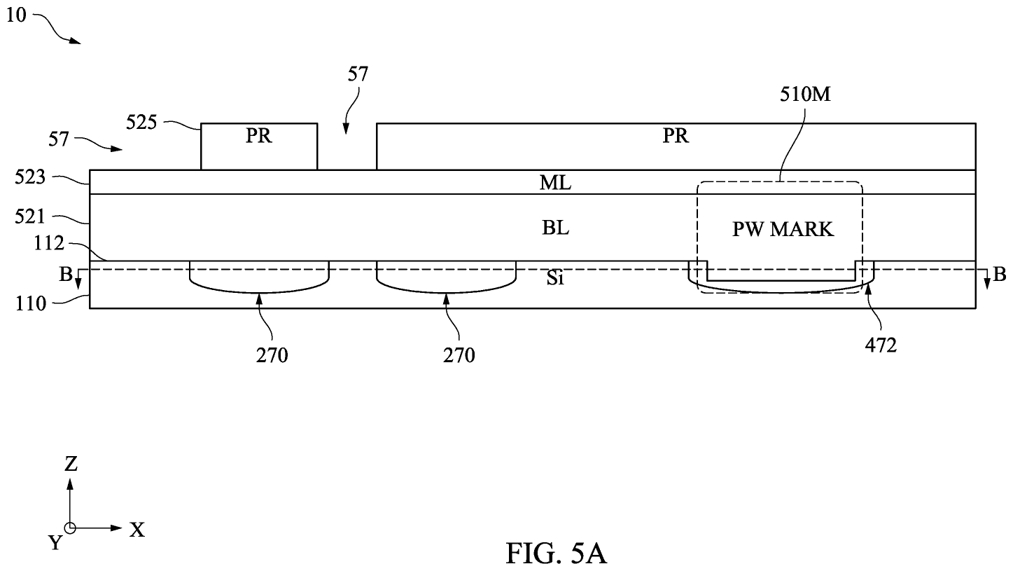

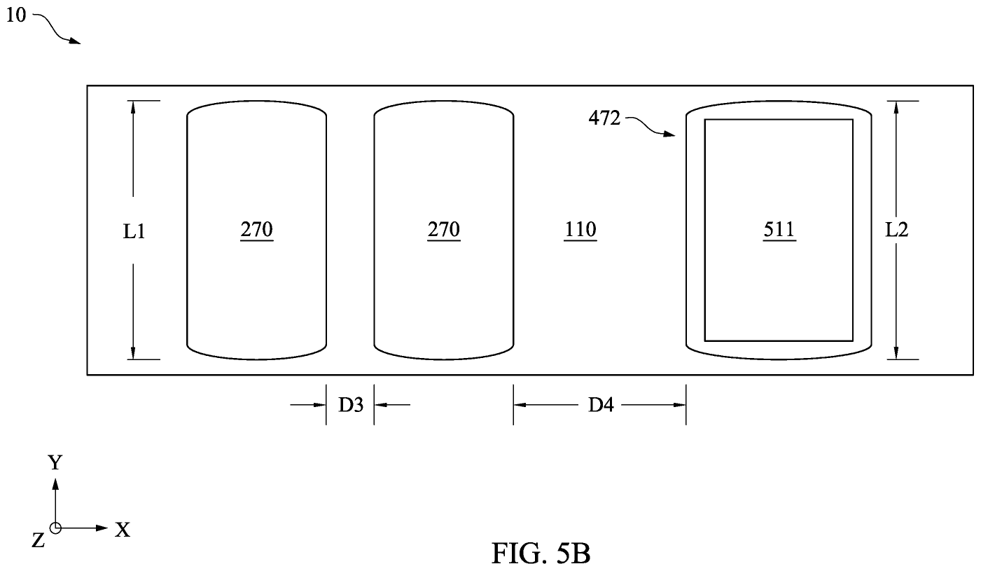

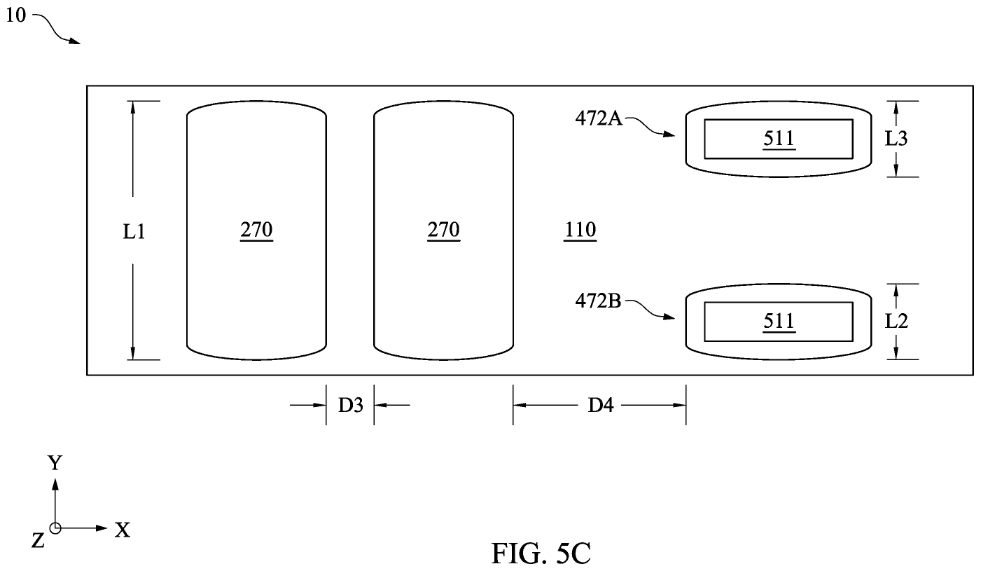

In FIGS. 5A-5C, following recessing to form the well alignment mark 472, the bottom mask layer 121 may be removed and another bottom mask layer 521 may be formed that fills and covers the opening 27B over the well alignment mark 472. In some embodiments, the bottom mask layer 521 is formed by filling the opening 27B back in instead of replacing the entire bottom mask layer 121. Following formation of the bottom mask layer 521, a second middle mask layer 523 is formed on the bottom mask layer 521. Then, a photosensitive layer 525 or photoresist layer 525 is formed on the second middle mask layer 523. Formation and composition of the bottom mask layer 521, the second middle mask layer 523 and the photosensitive layer 525 may be similar to or the same as those of the bottom mask layer 121, the middle mask layer 123 and the photosensitive layer 125 described with reference to FIG. 1.

The photosensitive layer 525 may be patterned to form openings 57 through which n-type wells or n-wells will be formed in a subsequent operation. Patterning of the photosensitive layer 525 may be similar to that described with reference to FIG. 1. The openings 57 overlap areas between the first wells 270 along the X-axis direction, as shown. In some embodiments, edges of the openings 57 may partially overlap edges of the first wells 270. The openings 57 may be formed via patterning using DUV light generated by a ArF excimer laser at wavelength of about 193 nm. The openings 57 are formed using the well alignment mark 472 for alignment. This is beneficial to obtain accurate alignment relative to the first wells 270.

FIGS. 5B and 5C are diagrammatic cross-sectional top views along the sectional line B-B of FIG. 5A. In FIG. 5B, the first wells 270 are separated from each other by a distance D3 and the well alignment mark 472 is separated from the first wells 270 by a distance D4. In some embodiments, the distance D4 exceeds the distance D3. The first wells 270 have length L1 in the Y-axis direction and the well alignment mark 472 has length L2 in the Y-axis direction. In some embodiments, the first wells 270 have different length from each other. In some embodiments, the first wells 270 have different shape than that depicted in FIG. 5B. For example, the first wells 270 may be L-shaped or C-shaped instead of being linear. In some embodiments, the length L1 is substantially the same as the length L2. In some embodiments, the length L1 is different than the length L2. For example, the length L1 may exceed the length L2. Namely, the first wells 270 may be elongated features, whereas the well alignment mark(s) 472 may not be elongated (e.g., may be square-shaped or circle-shaped).

The well alignment mark 472 laterally surrounds the bottom mask layer 511 in the recess. Namely, the bottom mask layer 511 is in the recess of the well alignment mark 472 and the well alignment mark 472 has walls that enclose the recess in the XY plane. In some embodiments, an area ratio of the recess as a percentage of total area of the well alignment mark 472 is in a range of about 20% to about 90%. Over about 90%, risk of breaking through the surrounding region of the well alignment mark 472 that is around the recess may be increased, which may degrade optical identifiability of the well alignment mark 472 during a photolithography operation. Below about 20%, the well alignment mark 472 may not be sufficiently clear or distinguishable as a basis for alignment during the photolithography operation.

FIG. 5C depicts an embodiment in which two well alignment marks 472A, 472B are adjacent the first wells 270. A first well alignment mark 472A has a length L2 in the Y-axis direction and a second well alignment mark 472B has a length L3 in the Y-axis direction. The lengths L2, L3 are shorter than the length L1 of the first wells 270. In some embodiments, the lengths L2, L3 are substantially the same. In some embodiments, the lengths L2, L3 are different. Namely, one of the well alignment marks 472A, 472B may be elongated and the other thereof may be short in the Y-axis direction. Generally, the well alignment marks 472A, 472B may be fully aligned with each other along the Y-axis direction. However, in some embodiments, the well alignment marks 472A, 472B may be partially aligned with each other, such that one of the well alignment marks 472A, 472B is closer to the first wells 270 than the other.

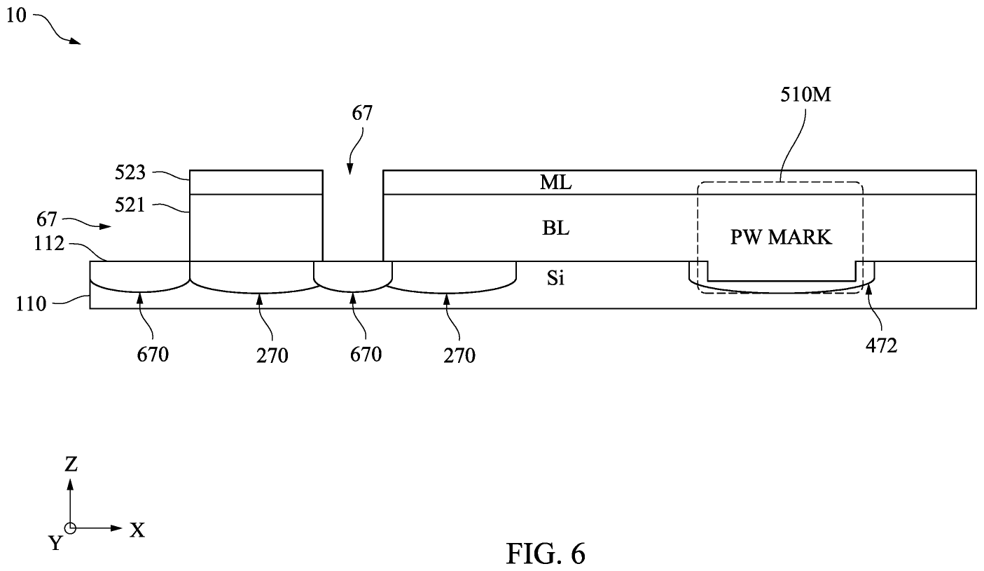

In FIG. 6, the openings 57 are extended to form openings 67 that expose the upper surface 112 of the substrate 110. Then, second wells 670 are formed in areas between and/or adjacent to the first wells 270. Formation of the second wells 670 is similar in most respects to formation of the first wells 270 described with reference to FIG. 2. Instead of p-type dopants, the second wells 670 may be formed via ion implantation of n-type dopant ions, such as phosphorus, arsenic, antimony or the like. In some embodiments, the second wells 670 have edge regions that merge with edge regions of the first wells 270. The second wells 670 may be formed to the same depths or different depths than the first wells 270. The second wells 670 may be narrower than the first wells 270 along the X-axis direction. In some embodiments, formation of the second wells 670 is omitted and the second wells 670 are not present.

Forming the second wells 670 under alignment of the well alignment mark 472 is beneficial to increase accuracy of alignment of the second wells 670 to the first wells 270. Up to a 40% improvement in alignment accuracy is achieved compared to alignment by zero mark.

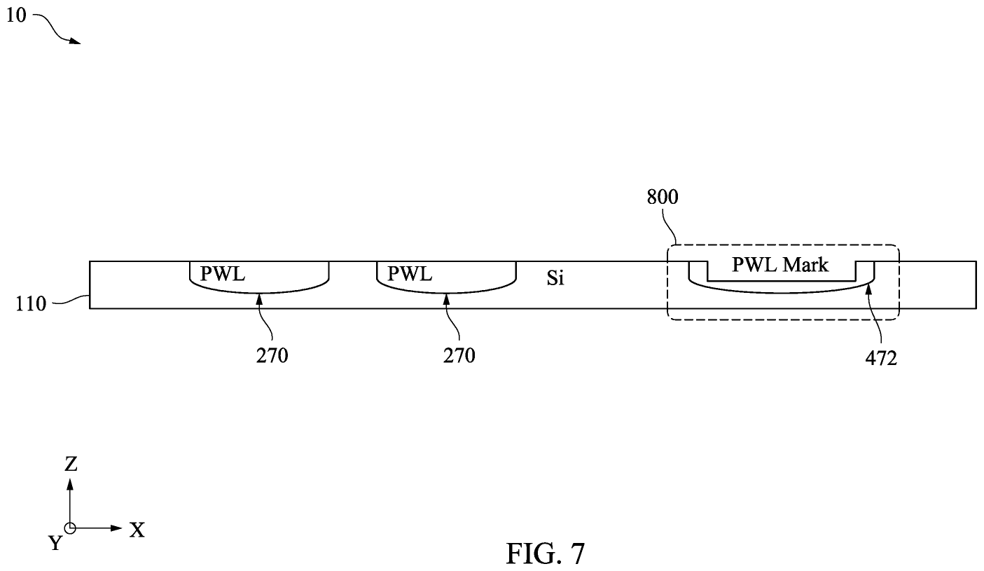

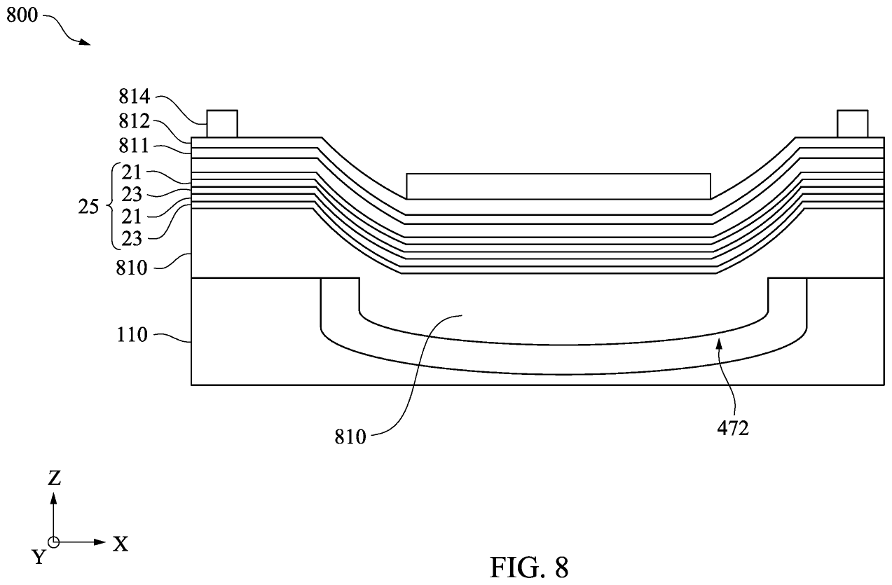

FIGS. 7-9 are diagrammatic cross-sectional side views that depict formation of an active area or OD (or fin 32 and stack 26) via alignment of the well alignment mark 472. In FIG. 7, the well alignment mark 472 is in a region 800 that is depicted in greater detail in FIG. 8. Prior to forming the OD, a number of operations may be performed that are described following to provide context.

Referring to FIG. 8, a multi-layer stack 25 or “lattice” is formed over the substrate 110 of alternating layers of first semiconductor layers 21 and second semiconductor layers 23, corresponding to act 1060 of FIG. 10. Three layers 21 are depicted in FIG. 8, but other number of the layers 21 (e.g., 2, 4 or more) may be formed. In some embodiments, the first semiconductor layers 21 may be formed of a first semiconductor material suitable for n-type nano-FETs, such as silicon, silicon carbide, or the like, and the second semiconductor layers 23 may be formed of a second semiconductor material suitable for p-type nano-FETs, such as silicon germanium or the like. Each of the layers 21, 23 of the multi-layer stack 25 may be epitaxially grown using a process such as chemical vapor deposition (CVD), atomic layer deposition (ALD), vapor phase epitaxy (VPE), molecular beam epitaxy (MBE), or the like.

Due to high etch selectivity between the first semiconductor materials and the second semiconductor materials, the second semiconductor layers 23 of the second semiconductor material may be removed without significantly removing the first semiconductor layers 21 of the first semiconductor material, thereby allowing the first semiconductor layers 21 to be patterned to form channel regions of nano-FETs. In some embodiments, the first semiconductor layers 21 are removed and the second semiconductor layers 23 are patterned to form channel regions. The high etch selectivity allows the first semiconductor layers 21 of the first semiconductor material to be removed without significantly removing the second semiconductor layers 23 of the second semiconductor material, thereby allowing the second semiconductor layers 23 to be patterned to form channel regions of nano-FETs.

In FIG. 8, prior to forming the lattice 25, a layer 810 may be formed that fills (partially or fully) the recess of the well alignment mark 472. The layer 810 may be undoped silicon in some embodiments. The layer 810 may have an upper surface that inherits profile of the recess. Namely, the upper surface of the layer 810 may dip down and have lower height over the recess and have taller height on either side of the recess.

Following formation of the layer 810, the lattice 25 may be formed by alternately growing the second semiconductor layers 23 and the first semiconductor layers 21 as described above.

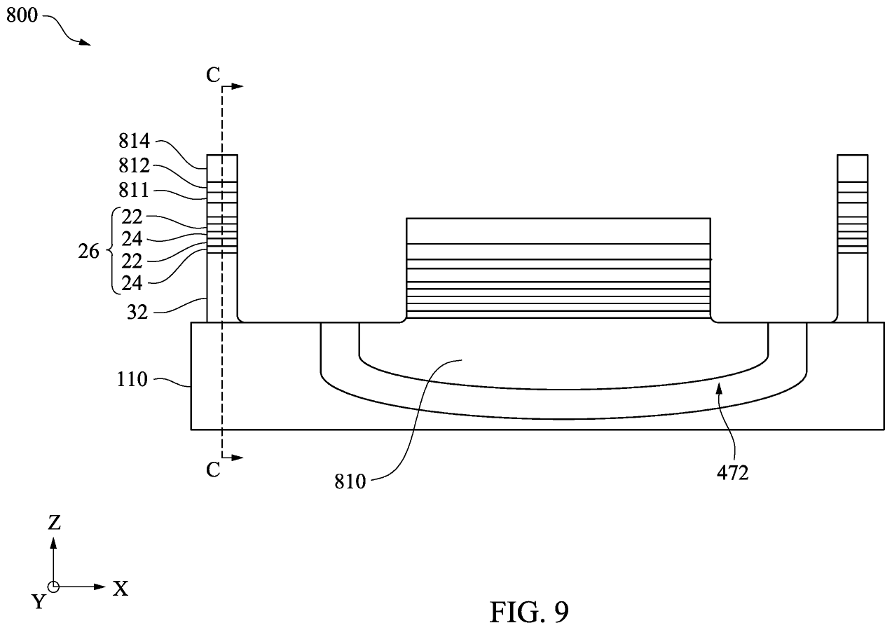

In FIG. 9, fins 32 are formed in the layer 810 and optionally in the substrate 110 and nanostructures 22, 24 are formed in the multi-layer stack 25 to form a vertical stack 26 of channels 22. In some embodiments, the nanostructures 22, 24 and the fins 32 may be formed by etching trenches in the multi-layer stack 25, the layer 810 and optionally the substrate 110. The etching may be any acceptable etch process, such as a reactive ion etch (RIE), neutral beam etch (NBE), the like, or a combination thereof. The etching may be anisotropic. For example, a third mask that includes an oxide layer 811 and one or more hard mask layers or other appropriate mask layers 812, 814 may be formed over the multi-layer stack 25. The mask layers 812, 814 and the oxide layer 811 may be patterned, such that regions of the multi-layer stack 25 for forming active areas or ODs are covered by the mask layers 812, 814 and the oxide layer 811, and other regions outside the active areas or ODs are exposed by the mask layers 812, 814 and the oxide layer 811. Then, the etching may be performed to recess the other regions, forming the fins 32 and the vertical stacks 26 of nanostructures 22, 24, the resulting structure being depicted in FIG. 9.

First nanostructures 22 (also referred to as “channels 22” below) are formed from the first semiconductor layers 21, and second nanostructures 24 are formed from the second semiconductor layers 23. Distance between adjacent fins 32 and nanostructures 22, 24 may be from about 18 nm to about 100 nm. A portion of the device 10 is illustrated in FIG. 9, including a single fin 32 on either side of the well alignment mark 472 for simplicity of illustration.

Using the well alignment mark 472 to align formation of the fins 32 is beneficial to improve alignment accuracy during a photolithography operation that exposes regions outside the fins 32 for removal in the anisotropic etching process described above.

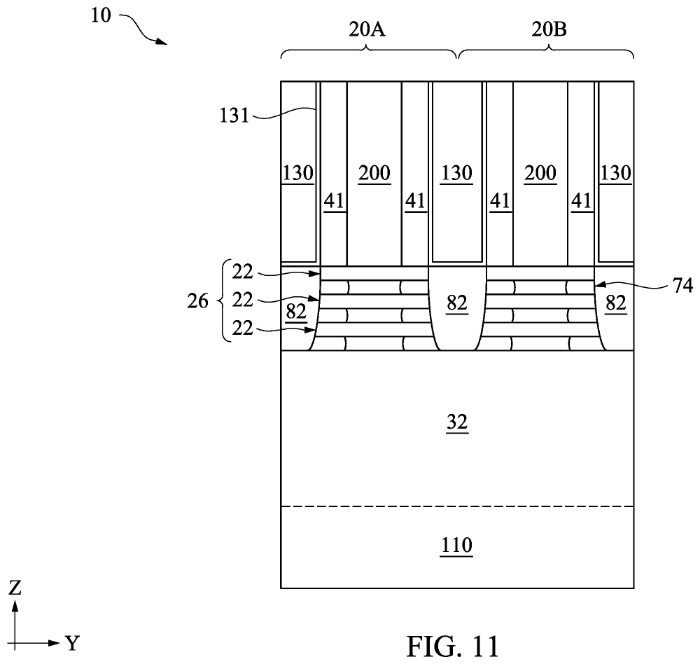

FIG. 11 is a diagrammatic cross-sectional side view of a portion of the IC device 10 along the line C-C depicted in FIG. 9. Following formation of the fins 32, further processing may be performed to form active devices 20A, 20B of the IC device 10. For example, shallow trench isolations (STIs) may be formed between neighboring fins 32. Sacrificial gates may be formed across the fins 32, and regions of the fins 32 exposed by the sacrificial gates may be recessed to form nanosheet channels 22 of individual transistors 20A, 20B. Source/drain regions 82 may be epitaxially grown between adjacent stacks 26 of nanosheet channels 22. The sacrificial gates may be replaced with active gates 200. The active gates 200 or gate structures 200 may wrap around the nanosheet channels 22. Then, contacts may be formed to provide electrical connection with the source/drain regions and the active gates. The source/drain contacts maybe formed through an interlayer dielectric (ILD) 130 and an etch stop layer 131. The source/drain contacts may be separated from the active gates 200 by sidewall spacers 41. The source/drain regions 82 may be separated from the active gates 200 by inner spacers 74 present between the nanosheet channels 22. Further interconnect structures including metal layers embedded in interlayer dielectrics (ILDs) may be built up over the contacts to provide electrical interconnection between devices (e.g., transistors, capacitors, and the like) of the IC device 10.

Embodiments may provide advantages. By forming the well alignment mark 472 in the same process as the first wells 270, alignment between the first wells 270 and the second wells 670 and alignment between the first wells 270 and the fins 32 are improved.

In accordance with at least one embodiment, a method includes: forming a first mask over a substrate; forming first openings and a second opening in the first mask; forming first wells in first regions of the substrate exposed by the first openings and an alignment implant in a second region of the substrate exposed by the second opening; forming an alignment mark by recessing the alignment implant; and patterning a multi-layer semiconductor lattice under alignment of the alignment mark.

In accordance with at least one embodiment, a device includes: a substrate; a first well of a first doping type in the substrate; an alignment mark in the substrate, the alignment mark including the first doping type; a stack of semiconductor nanostructures over the first well; a source/drain region in contact with the stack; and a gate structure wrapping around the semiconductor nanostructures.

In accordance with at least one embodiment, a method includes: in a same implantation operation, forming first wells in first regions of a substrate and an alignment implant in a second region of the substrate offset from the first regions; forming an alignment mark by recessing the alignment implant in a self-aligned process while the first wells are masked; and patterning a multilayer semiconductor lattice under alignment of the alignment mark.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first mask over a substrate;
forming first openings and a second opening in the first mask;
forming first wells in first regions of the substrate exposed by the first openings and an alignment implant in a second region of the substrate exposed by the second opening;
forming an alignment mark by recessing the alignment implant; and
patterning a multi-layer semiconductor lattice under alignment of the alignment mark.

2. The method of claim 1, further comprising:
forming a second mask over the substrate;
forming third openings in the second mask; and
forming second wells in third regions of the substrate exposed by the third openings, the second wells being of different type than the first wells.

3. The method of claim 2, wherein the forming first wells includes forming P-type wells.

4. The method of claim 2, wherein the forming a second mask includes:
forming a first mask layer on the substrate, the first mask layer extending into a recess over the alignment mark; and
forming a second mask layer over the first mask layer.

5. The method of claim 1, further comprising:
depositing a semiconductor material layer in a third opening over the alignment mark; and
forming the multi-layer semiconductor lattice by depositing alternating first semiconductor layers and second semiconductor layers on the semiconductor material layer and the substrate.

6. The method of claim 1, wherein the recessing the alignment implant is etching the alignment implant partially without breaking through the alignment implant.

7. The method of claim 1, The method of claim 1, wherein the recessing the alignment implant is etching the alignment implant partially such that vertical sidewalls of the alignment implant remain in the alignment mark.

8. A device, comprising:
a substrate;
a first well of a first doping type in the substrate;
an alignment mark in the substrate, the alignment mark including the first doping type;
a stack of semiconductor nanostructures over the first well;
a source/drain region in contact with the stack; and
a gate structure wrapping around the semiconductor nanostructures.

9. The device of claim 8, wherein the alignment mark extends to substantially the same depth in the substrate as the first well.

10. The device of claim 8, wherein the first well and the alignment mark include P-type dopants.

11. The device of claim 8, wherein a semiconductor layer is positioned on the alignment mark, the semiconductor layer being in contact with vertical sidewalls of the alignment mark and extending to a level coplanar with upper surfaces of the vertical sidewalls.

12. The device of claim 8, further comprising an opening in the alignment mark, the opening extending to a depth that is shallower than a lower surface of the alignment mark.

13. The device of claim 8, further comprising a second well adjacent the first well, the second well being a different doping type than the first well.

14. A method, comprising:
in a same implantation operation, forming first wells in first regions of a substrate and an alignment implant in a second region of the substrate offset from the first regions;
forming an alignment mark by recessing the alignment implant in a self-aligned process while the first wells are masked; and
patterning a multilayer semiconductor lattice under alignment of the alignment mark.

15. The method of claim 14, further comprising:
forming a bottom mask layer on the substrate;
forming a middle mask layer on the bottom mask layer; and
forming a photosensitive layer on the middle mask layer;
wherein the forming an alignment implant and the recessing the alignment implant are performed through a same opening in the bottom mask layer.

16. The method of claim 15, further comprising:
removing the bottom mask layer;
forming a second bottom mask layer, the second bottom mask layer covering the alignment mark; and
forming second wells of a different dopant type than the first wells, the forming second wells being through openings in the second bottom mask layer.

17. The method of claim 15, further comprising after the forming an alignment implant:
forming a second photosensitive layer covering the first wells and exposing the same opening through which the alignment implant is recessed.

18. The method of claim 14, wherein the forming first wells includes forming the first wells having width in a first direction that does not exceed width of the alignment implant in the first direction.

19. The method of claim 18, wherein the forming an alignment implant includes forming the alignment implant having length in a second direction that does not exceed length of the first wells in the second direction, the second direction being transverse the first direction.

20. The method of claim 19, further including forming a plurality of alignment implants during the forming first wells, the plurality of alignment implants being arranged along the second direction, a total length of the plurality of alignment implants not exceeding the length of the first wells.
